(19) United States
(12) Patent Application Publication
(10) Pub. No.: US 2015/0036429 A1
(43) Pub. Date: Feb. 5, 2015

(54) SEMICONDUCTOR MEMORY DEVICE

(71) Applicant: SK hynix Inc., Icheon-si Gyeonggi-do (KR)

(72) Inventors: Nam Kuk KIM, Yongin-si Gyeonggi-do (KR); Nam Jae LEE, Cheongju-si Chungcheongbuk-do (KR); Kwang Hee HAN, Cheongju-si Chungcheongbuk-do (KR); Il Chaek KIM, Seoul (KR); Sang Hyun AN, Cheongju-si Chungcheongbuk-do (KR)

(73) Assignee: SK hynix Inc., Icheon-si Gyeonggi-do (KR)

(21) Appl. No.: 14/074,310

(22) Filed: Nov. 7, 2013

(30) Foreign Application Priority Data
Jul. 30, 2013 (KR) 10-2013-0090200

(51) Int. Cl. G11C 16/04; H01L 27/115

(52) U.S. Cl. CPC G11C 16/0425; H01L 27/11551; H01L 27/11578
USPC 365/185.05; 365/185.18; 257/314

(57) ABSTRACT

A semiconductor memory device includes a memory block including memory strings formed between bit lines and a source line, wherein the bit lines and the source line are formed on a substrate, each of the memory strings includes a superordinate cell string connected between the bit line and pipe transistors formed on the substrate and a subordinate cell string connected between the source line and the pipe transistors, and an operation circuit configured to apply operation voltages to the memory strings to perform a program operation and apply different voltages to the pipe transistors of the memory strings connected to the same bit line in the memory block.

### CROSS-REFERENCE TO RELATED APPLICATION

The present application claims priority under 35 U.S.C. §119(a) to Korean patent application number 10-2013-0090200 filed on Jul. 30, 2013, in the Korean Intellectual Property Office, the entire disclosure of which is incorporated herein by reference in its entirety.

### BACKGROUND

1. Technical Field

The present invention generally relates to a semiconductor memory device, and more particularly, to a semiconductor memory device including a pipe transistor.

2. Related Art

To increase a data capacity, a larger number of memory cells should be formed in a predetermined area. Although a memory cell size has been reduced to achieve the object, there is a specific limit to reducing the memory cell size. In another method, a 3-dimensional memory block (or memory string) in which memory cells are vertically stacked on a semiconductor substrate has been proposed. The 3-dimensional memory string may include a vertical channel formed of silicon.

In recent years, a method capable of preventing degradation of electrical properties due to formation of a 3-dimensional memory string is also required.

### SUMMARY

The present invention is directed to a semiconductor memory device capable of improving electrical properties.

One aspect of the present invention provides a semiconductor memory device including a first memory string including a first pipe transistor, a first superordinate cell string connected between a first bit line and the first pipe transistor, and a first subordinate cell string connected between the first pipe transistor and a source line, a second memory string including a second pipe transistor, a second superordinate cell string connected between a second bit line and the second pipe transistor, and a second subordinate cell string connected between the second pipe transistor and the source line, a third memory string including a third pipe transistor, a third superordinate cell string connected between the first bit line and the third pipe transistor, and a third subordinate cell string connected between the third pipe transistor and the source line, and a fourth memory string including a fourth pipe transistor, a fourth superordinate cell string connected between the second bit line and the fourth pipe transistor, and a fourth subordinate cell string connected between the fourth pipe transistor and the source line. Gates of the first and fourth pipe transistors are connected to each other, and gates of the second and third pipe transistors are connected to each other.

Another aspect of the present invention provides a semiconductor memory device including first and second pipe gates formed on a substrate, first and fourth horizontal channel layers formed in the first pipe gate, second and third horizontal channel layers formed in the second pipe gate, first conductive layers and second conductive layers stacked on different regions of the substrate, a source line and bit lines formed on the first and second conductive layers, second, third, sixth, and seventh vertical channel layers respectively connected between the first through fourth horizontal channel layers and the source line and formed through the first conductive layers, first and fifth vertical channel layers respectively connected between the first and third horizontal channel layers and a first bit line through the second conductive layers, and fourth and eighth vertical channel layers respectively connected between the second and fourth horizontal channel layers and a second bit line and formed through the second conductive layers.

Another aspect of the present invention provides a semiconductor memory device including a memory block including memory strings formed between bit lines and a source line, wherein the bit lines and the source line are formed on a substrate, each of the memory strings includes a superordinate cell string connected between the bit line and pipe transistors formed on the substrate and a subordinate cell string connected between the source line and the pipe transistors, and an operation circuit configured to apply operation voltages to the memory strings to perform a program operation and apply different voltages to the pipe transistors of the memory strings connected to the same bit line in the memory block.

Another aspect of the present invention provides a semiconductor memory device including a first memory string including a first pipe transistor, a first superordinate cell string connected between a first bit line and the first pipe transistor, and a first subordinate cell string connected between the first pipe transistor and a source line; a second memory string including a second pipe transistor, a second superordinate cell string connected between the source line and the second pipe transistor, and a second subordinate cell string connected between the second pipe transistor and a second bit line; a third memory string including a third pipe transistor, a third superordinate cell string connected between the first bit line and the third pipe transistor, and a third subordinate cell string connected between the third pipe transistor and the source line; a fourth memory string including a fourth pipe transistor, a fourth superordinate cell string connected between the source line and the fourth pipe transistor, and a fourth subordinate cell string connected between the fourth pipe transistor and the second bit line, wherein gates of the first and fourth pipe transistors are connected to each other, and gates of the second and third pipe transistors are connected to each other.

### BRIEF DESCRIPTION OF THE DRAWINGS

The above and other features and advantages of the present invention will become more apparent to those of ordinary skill in the art by describing in detail various examples of embodiments thereof with reference to the attached drawings in which:

FIG. 1 is a block diagram of a semiconductor memory device according to an embodiment of the present invention;

FIGS. 2A and 2B are diagrams of memory strings included in a memory block of FIG. 1;

FIGS. 3A through 3C are perspective views of a memory device included in the memory string of FIG. 2A;

FIG. 4 is a circuit diagram illustrating a connection relationship between the memory strings included in the memory block of FIG. 1;

FIG. 5 is a cross-sectional view illustrating a connection relationship between the memory strings included in the memory block of FIG. 1;

FIG. 6 is a plan view illustrating a connection relationship between the memory strings included in the memory block of FIG. 1;

FIG. 7 is a waveform diagram illustrating a method of operating a semiconductor memory device according to an embodiment of the present invention;

FIG. 8 is a block diagram of a memory system according to an embodiment of the present invention;

FIG. 9 is a block diagram of a fusion memory device or fusion memory system configured to perform a program operation; and

FIG. 10 is a block diagram of a computing system including a flash memory device according to an embodiment of the present invention.

### DETAILED DESCRIPTION

The present invention will now be described more fully hereinafter with reference to the accompanying drawings, in which various embodiments of the present invention are shown. This invention may, however, be embodied in different forms and should not be construed as limited to the embodiments set forth herein. Rather, these embodiments are provided so that this disclosure is thorough and complete and fully conveys the scope of the present invention to one skilled in the art.

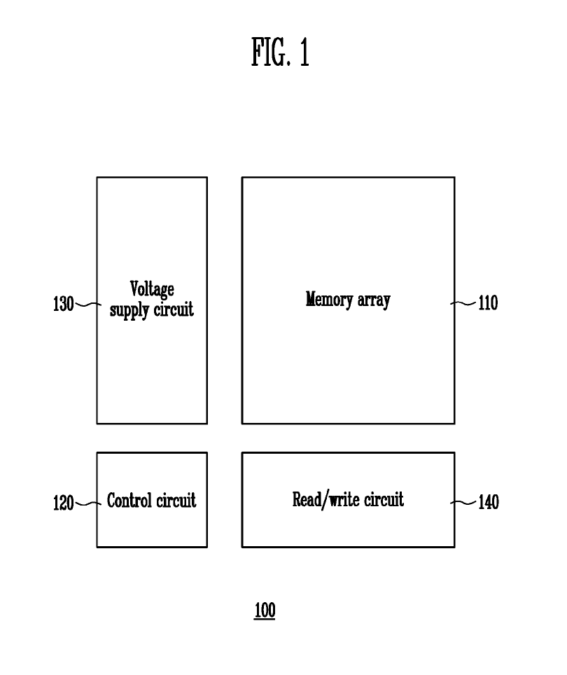

FIG. 1 is a block diagram of a semiconductor memory device according to an embodiment of the present invention.

Referring to FIG. 1, the semiconductor memory device 100 may include a voltage supply circuit 130, a memory array 110, and operation circuits 120 to 140 (i.e., control circuit 120 and Read/write circuit 140). The memory array 110 may include a plurality of memory blocks. Each of the memory blocks may include a plurality of memory strings. Each of the memory strings may include a plurality of memory cells. In the case of a flash memory device, each of the memory blocks may include flash memory cells. In an example, each of the memory blocks may include flash memory cells, each of which may include a flash gate formed of polysilicon (poly-Si) or a charge storage layer formed of a nitride layer.

In particular, each of the memory blocks may include memory strings respectively connected to bit lines and connected in parallel to a source line. The memory strings may be 2-dimensionally or 3-dimensionally formed on a semiconductor substrate. A memory block including 3-dimensional memory strings will now be described in further detail.

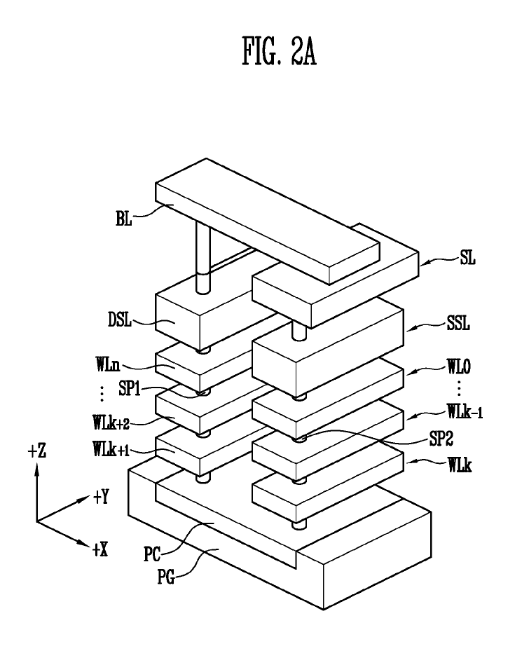

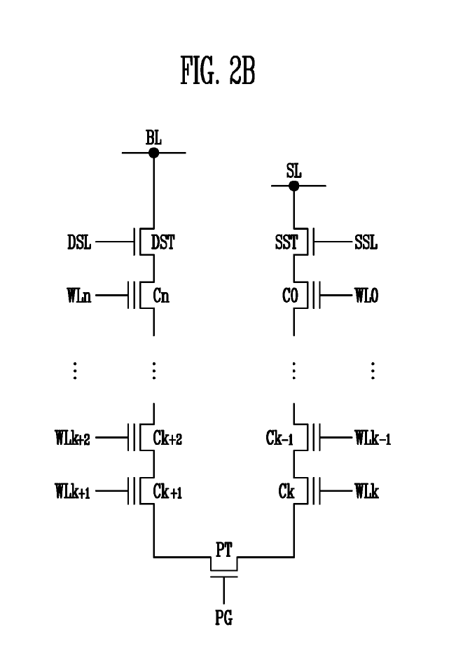

FIGS. 2A and 2B are diagrams of the memory string included in the memory block of FIG. 1.

Referring to FIGS. 2A and 2B, a pipe gate PG including a recess unit may be formed on a semiconductor substrate (not shown), and a pipe channel layer PC may be formed in the recess unit of the pipe gate PG. A plurality of vertical channel layers SP1 and SP2 may be formed on the pipe channel layer PC. Among a pair of vertical channel layers, an upper portion of a second vertical channel layer SP2 may be connected to a source line SL, and an upper portion of a first vertical channel layer SP1 may be connected to a bit line BL. The vertical channel layers SP1 and SP2 may be formed of poly-Si.

A plurality of conductive layers DSL and WLn to WLk+1 may be formed to surround the first vertical channel layer SP1 at different heights of the first vertical channel layer SP1. Also, a plurality of conductive layers SSL and WL0 to WLk may be formed to surround the second vertical channel layer SP2 at different heights of the second vertical channel layer SP2. A multilayered film (not shown) including a charge storage layer may be formed on the surfaces of the vertical channel layers SP1 and SP2 and the surface of the pipe channel layer PC. The multilayered film may be interposed between the vertical channel layers SP1 and SP2 and the conductive layers DSL, WLn to WLk+1, SSL, and WL0 to WLk and between the pipe channel layer PC and the pipe gate PC.

An uppermost conductive layer formed to surround the first vertical channel layer SP1 may become a drain selection line DSL, while lower conductive layers of the drain selection line DSL may become word lines WLn to WLk+1. Some of the conductive layers used as the word lines WL0 to WLk may be dummy word lines.

In other words, the first conductive layers SSL and WL0 to WLk and the second conductive layers DSL and WLn to WLk+1 may be stacked on different regions of the semiconductor substrate. The second vertical channel layer SP2 formed through the first conductive layers SSL and WL0 to WLk may be vertically connected between the source line SL and the pipe channel layer PC. The first vertical channel layer SP1 formed through the second conductive layers DSL and WLn to WLk+1 may be vertically connected between the bit line BL and the pipe channel layer PC.

A drain selection transistor DST may be formed at a portion in which the drain selection line DSL surrounds the first vertical channel layer SP1, while main cell transistors Cn to Ck+1 may be respectively formed at portions in which the word lines WLn to WLk+1 surround the first vertical channel layer SP1. A source selection transistor SST may be formed at a portion in which the source selection line SSL surrounds the second vertical channel layer SP2, while main cell transistors C0 to Ck may be respectively formed at portions in which the word lines WL0 to WLk surround the second vertical channel layer SP2.

Due to the above-described structure, the memory string may include the drain selection transistor DST and the main cell transistors Cn to Ck+1, which may be vertically connected to the substrate between the bit line BL and the pipe channel layer PC, and the source selection transistor SST and the main cell transistors C0 to Ck, which may be vertically connected to the substrate between the source line SL and the pipe channel layer PC. In the above-described structure, a dummy cell transistor may be further connected between the selection transistor DST or SST and the main cell transistor Cn or C0, and a dummy cell transistor may be further connected between the main cell transistor Ck+1 or Ck and the pipe transistor PT.

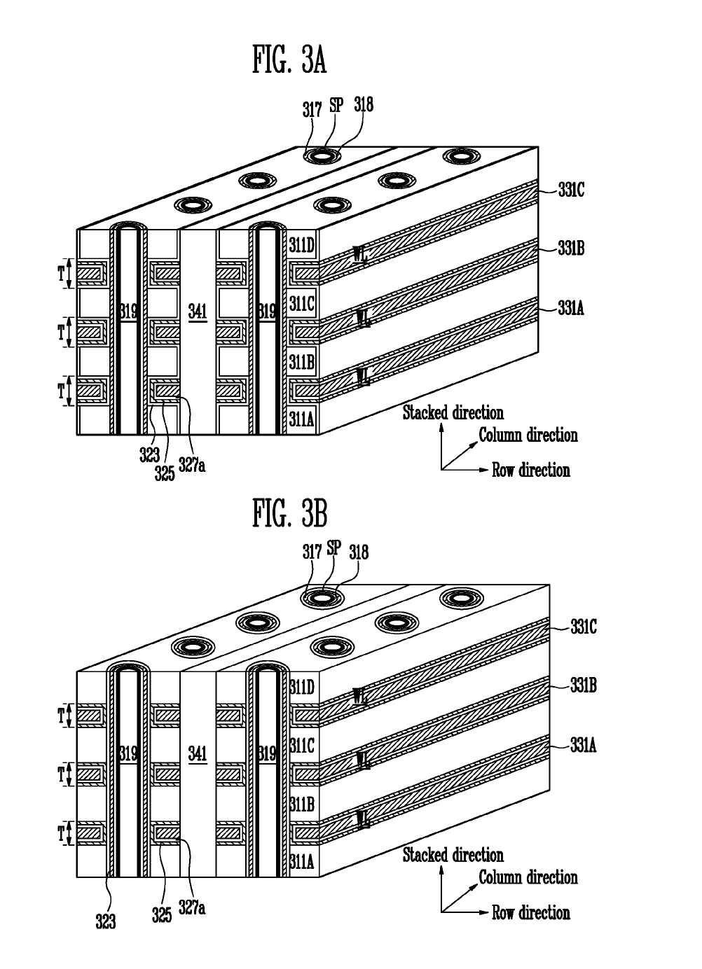

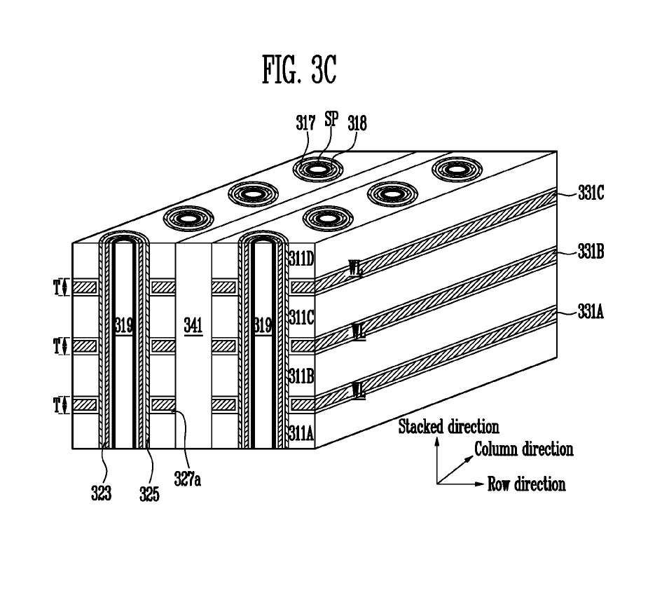

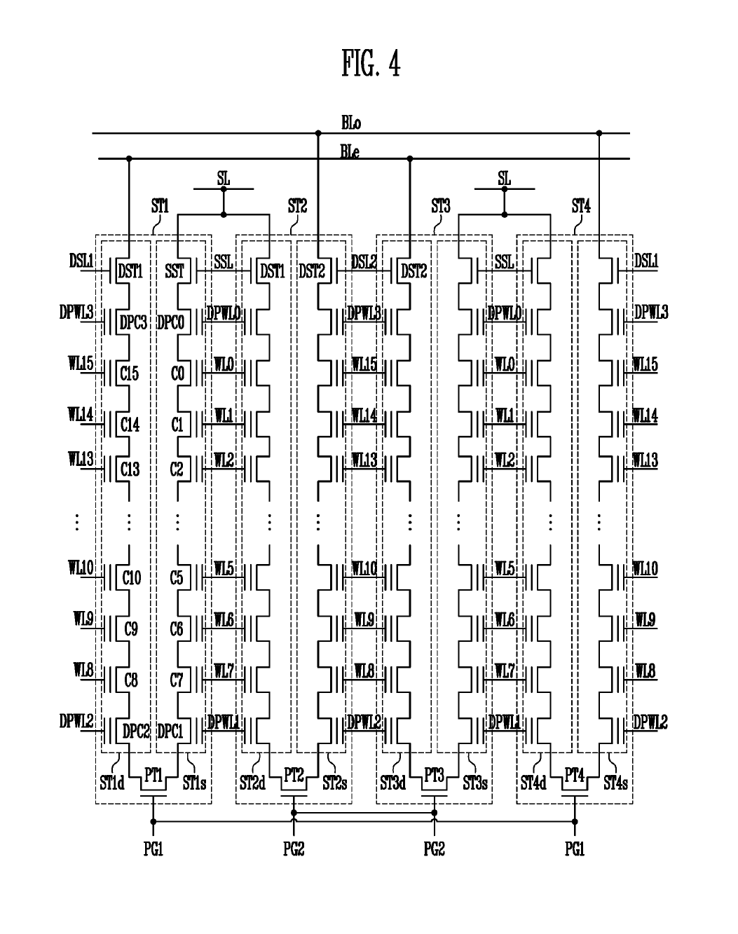

A structure of the memory cell formed with reference to FIG. 2A will now be described in further detail. FIGS. 3A through 3C are perspective views of a memory device included in the memory string of FIG. 2A.

Referring to FIGS. 3A through 3C, a 3-dimensional nonvolatile memory device according to various embodiments of the present invention may include vertical channel layers SP, which may protrude upward from a substrate (not shown) and constitute a matrix including a plurality of rows and a plurality of columns. Each of the vertical channel layers SP may be formed as a tube type having a central portion filled with an insulating layer 319 or as a pillar type having a surface and central portion formed of a semiconductor material layer.

The vertical channel layer SP may be surrounded with a plurality of interlayer insulating layers 311A to 311D and a plurality of conductive layers 331A to 331C stacked alternately. The plurality of interlayer insulating layers 311A to 311D and the plurality of conductive layers 331A to 331C may be formed between adjacent columns of the vertical channel layers SP and separated from an insulating layer 341, which may expand in a column direction through the plurality of interlayer insulating layers 311A to 311D.

Each of the conductive layers 331A to 331C may be formed within a trench T between adjacent ones of the interlayer insulating layers 311A to 311D. The conductive layers 331A to 331C may be separated from one another by trenches T. The trenches T may be spaces for defining regions in which word lines WL will be formed.

Each of the conductive layers 331A to 331C may be surrounded with a barrier metal pattern 327a. Barrier metal patterns 327a may be respectively formed within the trenches T and separated from one another by the trenches T.

Charge blocking layers 323 may be interposed between the vertical channel layers SP and the barrier metal patterns 327a, and a diffusion blocking layer 325 may be interposed between the barrier metal patterns 327a and the charge blocking layers 323. Also, charge storage layers 317 may be interposed between the charge blocking layers 323 and the vertical channel layers SP, and tunnel insulating layer 318 may be interposed between the charge storage layers 317 and the vertical channel layers SP.

The charge storage layers 317 and the tunnel insulating layers 318 may be formed to surround outer walls of the vertical channel layers SP.

Each of the charge blocking layers 323 may be formed along the surface of the trench T to surround the barrier metal pattern 327a as shown in FIG. 3A, or formed to surround an outer wall of the vertical channel layer SP as shown in FIGS. 3B and 3C.

The diffusion blocking layer 325 may be formed along the surface of the trench T to surround the barrier metal pattern 327a as shown in FIGS. 3A and 3B. Alternatively, when the diffusion blocking layer 325 is an insulating layer, the diffusion blocking layer 325 may be formed to surround the outer wall of the vertical channel layer SP as shown in FIG. 3C.

The conductive layers 331A to 331C disposed within the trenches T and the barrier metal patterns 327a formed to surround the conductive layers 331A to 331C may be used as word lines WL. Memory cell transistors may be defined at intersections between the word lines WL and the vertical channel layers SP. Due to the above-described structure, the memory cell transistors according to an embodiment of the present invention may be stacked along the vertical channel layers SP and 3-dimensionally arranged.

The conductive layers 331A to 331C may be formed of a poly-Si layer or a material layer having a lower resistance than the poly-Si layer and a large work function. For example, the conductive layers 331A to 331C may be formed of tungsten (W). When the conductive layers 331A to 331C are formed of a material layer having a large work function, back tunneling of charges toward the charge storage layers 317 through the charge blocking layers 323 may be reduced. When the back tunneling is reduced, retention characteristics of memory cells may increase.

The barrier metal patterns 327a may be formed of a material capable of inhibiting a reaction of the conductive layers 331A to 331C having a large work function with the charge blocking layers 323. Also, the barrier metal patterns 327a may be formed of a material layer having a large work function to reduce back tunneling.

Referring back to FIG. 1, the operation circuits 120, 130, and 140 may include a control circuit 120, a voltage supply circuit 130, and a read/write circuit 140.

The operation circuits 120 to 140 may be configured to perform a program operation, an erase operation, and a verification operation, and a read operation of memory cells included in selected memory strings. The operation circuits 120 to 140 may include the control circuit 120 configured to control the program operation, the erase operation, the verification operation, and the read operation and the voltage supply circuit 130 and the read/write circuit 140 configured to perform the program operation, the erase operation, the verification operation, and the read operation under the control of the control circuit 120.

To perform the program operation, the erase operation, the verification operation, and the read operation, the voltage supply circuit 130 may selectively output operation voltages to local lines (e.g., DSL1 and DSL2, DPWL0 to DPWL3, WL0 to WL15, SSL, PG1 and PG2 of FIG. 4) and a source line SL of a selected memory block. The read/write circuit 140 may be configured to control precharge/discharge operations of bit lines (BLe and BLo of FIG. 4) or sense the flow of current through the bit lines BLe and BLo. Respective components will now be described in detail.

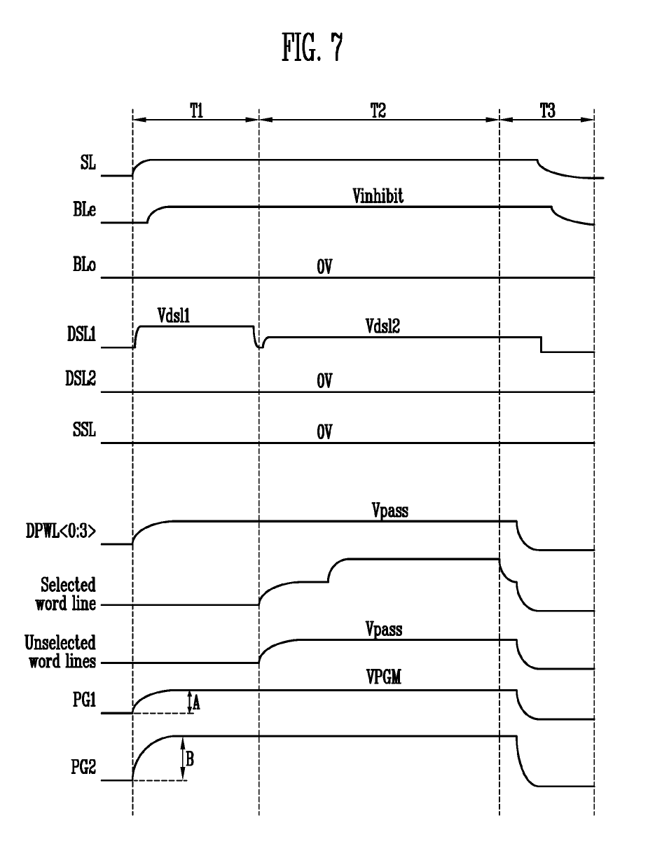

The control circuit 120 may output a voltage control signal for controlling the voltage supply circuit 130 so that the operation voltages (refer to FIG. 7) for performing the program operation, the erase operation, the verification operation, and the read operation can be generated at desired levels in response to an external command signal. Also, the control circuit 120 may output control signals for controlling read/write circuits (or page buffers) included in the read/write circuit 140 to perform the program operation, the erase operation, the verification operation, and the read operation. Also, when an address signal is input, the control circuit 120 may generate a column address signal and a row address signal in response to the address signal. Here, a selected memory block and word line may be determined according to a row address, and operation voltages applied to the selected word line and unselected word lines may vary according to the row address.

The control circuit 120 may control the voltage supply circuit 130 and the read/write circuit 140 so that a program loop including a program operation and a program verification operation is performed in an increment step pulse programming (ISPP) mode. Also, the control circuit 120 may control the voltage supply circuit 130 and the read/write circuit 140 so that an erase loop including an erase operation and an erase verification operation is performed in an increment step pulse erasing (ISPE) mode.

The voltage supply circuit 130 may generate operation voltages (e.g., an erase voltage, a program voltage, a pass voltage, a read voltage, a pipe gate voltage, a selection gate voltage, a program inhibition voltage, a program allowance voltage, and a ground voltage) required for the program operation, the erase operation, the verification operation, and the read operation of the memory cells in response to the voltage control signal of the control circuit 120, and selectively output the operation voltages to the local lines and the source line SL of the selected memory block in response to the row address signal of the control circuit 120.

The voltage supply circuit 130 may include a voltage generating circuit (not shown) and a row decoder (not shown). The voltage generating circuit may generate operation voltages in response to the voltage control circuit of the control circuit 120, and the row decoder may the operation voltages to the local lines and the source line of the selected memory block of the memory blocks in response to the row address signal of the control circuit 120. As described above, the operation voltages may be output and changed by the voltage supply circuit 130 in response to the voltage control signal of the control circuit 120 as described below.

The read/write circuit 140 may be connected to the memory blocks of the memory array 110 through the bit lines. At a program operation, the read/write circuit 140 may selectively precharge the bit lines in response to the control signal of the control circuit 120 and data to be stored in the memory cells. At a program verification operation or a read operation, in response to the control signal of the control circuit 120, the read/write circuit 140 may precharge the bit lines, sense variations in the voltages of the bit lines or current, and latch data read from the memory cells.

The above-described method of operating the components will be described in detail with reference to FIG. 7.

Hereinafter, a connection relationship between the memory strings included in the memory block will be described in further detail.

FIG. 4 is a circuit diagram illustrating the connection relationship between the memory strings included in the memory block of FIG. 1.

Referring to FIG. 4, the memory block may include a plurality of memory strings, and each of the bit lines may be connected to two memory strings. That is, the memory block may include memory strings (ST1 and ST3; only two memory strings are illustrated for brevity) connected between first bit lines or even bit lines (BLe; only one even bit line is illustrated for brevity) and the source line SL, and memory strings (ST2 and ST4; only two memory strings are illustrated for brevity) connected between two bit lines or odd bit lines (BLo; only one odd bit line is illustrated for brevity) and the source line SL. In particular, in the memory block, gates PG1 and PG2 of pipe transistors PT1 and PT3 of the memory strings ST1 and ST3 connected to the even bit line BLe may be separated from one another, while gates PG2 and PG1 of pipe transistors PT2 and PT4 of the memory strings ST2 and ST4 connected to the odd bit line BL0 may be separated from each other. Also, in the memory block, the gates PG1 of the pipe transistors PT1 and PT4 of the memory strings ST1 and ST4 respectively connected to the even bit line BLe and the odd bit line BLo may be connected to each other, while the gates PG2 of the pipe transistors PT2 and PT3 of the memory strings ST2 and ST3 respectively connected to the even bit line BLe and the odd bit line BLo may be connected to each other. This will now be described in further detail.

In the memory block, a first memory string ST1 and a third memory string ST3 may be connected between the even bit line BLe and the source line SL. In the memory block, a second memory string ST2 and a fourth memory string ST4 may be connected between the odd bit line BLo and the fourth memory string ST4. The bit lines BLe and BLo and the source line SL may be formed on the substrate. Each of the memory strings may include a pipe transistor, which may be formed on the substrate.

The first memory string ST1 may include a first pipe transistor PT1, a first superordinate cell string ST1d, and a first subordinate cell string ST1s. The first superordinate cell string ST1d may be connected between the even bit line BLe and the first pipe transistor PT1, while the first subordinate cell string ST1s may be connected between the first pipe transistor PT1 and the source line SL.

The second memory string ST2 may include a second pipe transistor PT2, a second superordinate cell string ST2d, and a second subordinate cell string ST2s. The second superordinate cell string ST2d may be connected between the odd bit line BLo and the second pipe transistor PT2, while the second subordinate cell string ST2s may be connected between the second pipe transistor PT2 and the source line SL.

The third memory string ST3 may include a third pipe transistor PT3, a third superordinate cell string ST3d, and a third subordinate cell string ST3s. The third superordinate cell string ST3d may be connected between the even bit line BLe and the third pipe transistor PT3, while the third subordinate cell string ST3s may be connected between the third pipe transistor PT3 and the source line SL.

The fourth memory string ST4 may include a fourth pipe transistor PT4, a fourth superordinate cell string ST4d, and a fourth subordinate cell string ST4s. The fourth subordinate cell string ST4s may be connected between the odd bit line BLo and the fourth pipe transistor PT4, while the fourth superordinate cell string ST4s may be connected between the fourth pipe transistor PT4 and the source line SL

The gates PG1 of the first and fourth pipe transistors PT1 and PT4 may be connected to each other, and the gates PG2 of the second and third pipe transistors PT2 and PT3 may be connected to each other.

Subordinate cell strings may include a source selection transistor SST connected to the source line SL and memory cells C0 to C7 connected to the source selection transistor SST. Subordinate cell strings may further include a first dummy pass memory cell DPC0 connected between the source selection transistor SST and the memory cell C0 and further include a second dummy pass memory cell DPC1 connected to a final memory cell C7 of the memory cells. Subordinate cell strings may include at least one of the first and second dummy pass memory cells DPC0 and DPC1.

Superordinate cell strings may include a drain selection transistor (e.g., DST1) connected to a bit line (e.g., BLe) and memory cells C15 to C8 connected to a drain selection transistor (e.g., DST1). Gates (or drain selection lines DSL1) of drain selection transistors DST1 included in the first and fourth superordinate cell strings ST1d and ST4d may be connected to each other, while gates (or drain selection lines DSL2) of drain selection transistors DST2 included in the second and third superordinate cell strings ST2d and ST3d may be connected to each other. Also, superordinate cell strings may further include a third dummy pass memory cell DPC2 connected to the final memory cell C8 of the memory cells C15 to C8 and further include a fourth dummy transistor DPC3 connected between a drain selection transistor and the memory cell C15.

Memory strings (e.g., ST1 and ST3) connected to the same bit line (e.g., BLe) in the memory block may respectively include drain selection transistors DST1 and DST2 having gates (or drain selection lines DSL1 and DSL2) separated from each other. Accordingly, at a program operation, only one memory string of the memory strings (e.g., ST1 and ST3) may be electrically connected to the bit line by the drain selection transistors DST1 and DST2. That is, a program operation may be performed on only one of the memory strings (e.g., ST1 and ST3) connected to the same bit line (e.g., BLe).

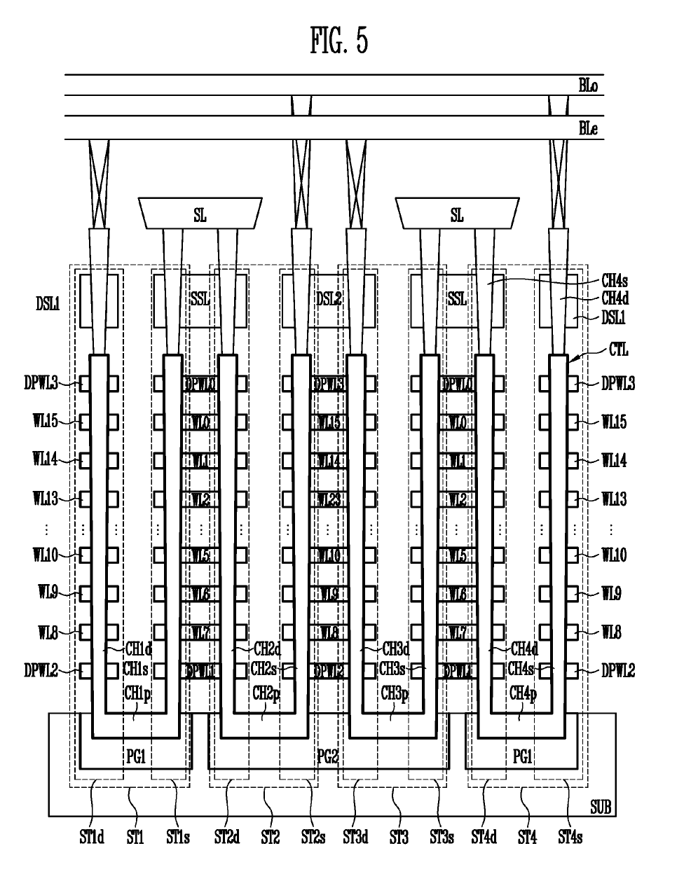

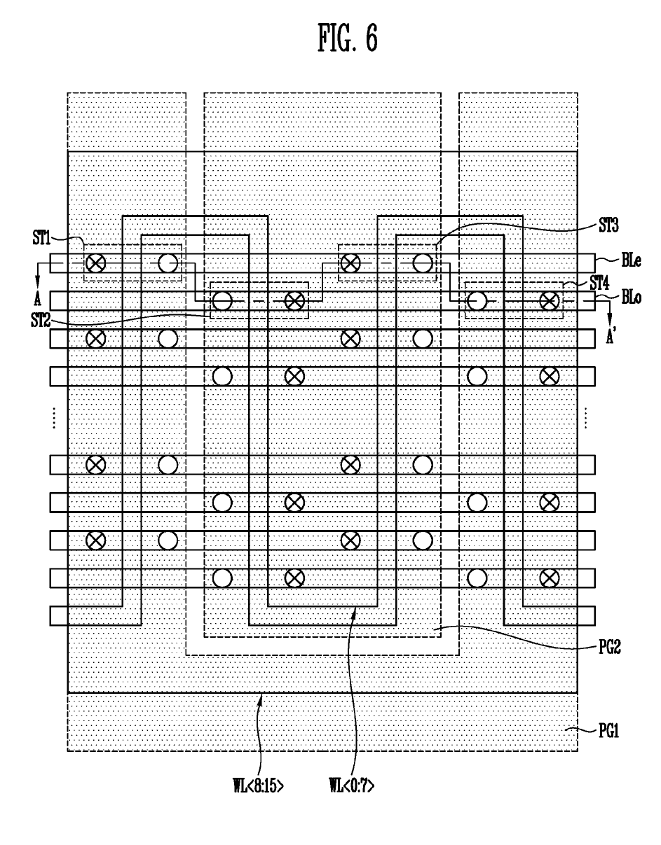

Hereinafter, a cross-sectional structure and planar structure of the above-described memory block will be described. FIG. 5 is a cross-sectional view illustrating a connection relationship between the memory strings included in the memory block of FIG. 1. FIG. 6 is a plan view illustrating the connection relationship between the memory strings included in the memory block of FIG. 1.

Referring to FIGS. 5 and 6, the memory block may include first and second pipe gates PG1 and PG2, first through fourth horizontal channels CH1p to CH4p, first conductive layers SSL, DPWL0, WL0 to WL7, and DPWL1, second conductive layers DSL (i.e., DSL1 and DSL2), DPWL3, WL15 to WL8, and DPWL2, and first through eighth vertical channel layers CH1d to CH4d and CH1s to CH4s.

The first and second pipe gates PG1 and PG2 of the memory block may be formed on a substrate SUB. Also, an insulating layer (not shown) may be further formed between the first and second pipe gates PG1 and PG2 and the substrate SUB. The first and fourth horizontal channel layers CH1p and CH4p may be formed in a first pipe gate PG1. Specifically, trenches may be formed in the first pipe gate PG1, and the first and fourth horizontal channel layers CH1p and CH4p may be respectively formed in the trenches of the first pipe trench PG1. The second and third horizontal channel layers CH2p and CH3p may be formed in a second pipe gate PG2. Specifically, trenches may be formed in the second pipe gate PG2, and second and third horizontal channel layers CH2p and CH3p may be respectively formed in the trenches of the second pipe gate PG2.

The first conductive layers SSL, DPWL0, WL0 to WL7, and DPWL1 and the second conductive layers DSL, DPWL3, WL15 to WL8, and DPWL2 may be stacked on different regions of the substrate SUB.

The source line SL and the bit lines BLe and BLo may be formed on the substrate SUB including the first and second conductive layers SSL, DPWL0, WL0 to WL7, DPWL1, DSL, DPWL3, WL15 to WL8, and DPWL2.

The second, third, sixth, and seventh vertical channel layers CH1s to CH4s may be respectively connected between the first through fourth horizontal channel layers CH1p to CH4p and the source line SL and formed through the first conductive layers SSL, DPWL0, WL0 to WL7, and DPWL1. The first through fifth vertical channel layers CH1d and CH3d may be respectively connected between the first and third horizontal channel layers CH1p and CH3p and a first bit line BLe, and formed through the second conductive layers DSL, DPWL3, WL15 to WL8, and DPWL2. The fourth and eighth vertical channel layers CH2d and CH4d may be respectively formed between the second and fourth horizontal channel layers CH2p and CH4p and a second bit line BLo, and formed through the second conductive layers DSL, DPWL3, WL15 to WL8, and DPWL2.

Additionally, charge storage layers CTL may be further provided between the second, third, sixth, and seventh vertical channel layers CH1s to Ch4s and between the first conductive layers SSL, DPWL0, WL0 to WL7, and DPWL1 and between the first, fourth fifth, and eighth vertical channel layers CH1d to CH4d and the second conductive layers DSL, DPWL3, WL15 to WL8, and DPWL2. The charge storage layers CTL may be disposed also between the pipe channel layers CH1p to CH4p and the pipe gates PG1 and PG2.

The first pipe gate PG1 may surround the second pipe gate PG2.

An uppermost conductive layer of the first conductive layers SSL, DPWL0, WL0 to WL7, and DPWL1 may become a source selection line SSL, and the remaining conductive layers may become word lines WL0 to WL7. Additionally, a conductive layer disposed under the uppermost conductive layer SSL and a lowermost conductive layer may become dummy pass word lines DPWL0 and DPWL1.

An uppermost conductive layer of the second conductive layers DSL, DPWL3, WL15 to WL8, and DPWL2 may become a drain selection line DSL, and the remaining conductive layers may become word lines WL8 to WL15. Additionally, a conductive layer disposed under the uppermost conductive layer DSL and a lowermost conductive layer may become dummy pass word lines DPWL2 and DPWL3.

The first bit line (or even bit line) BLe and the second bit line (or odd bit line) BLo may be formed in the form of lines parallel to each other. Since the first and third memory strings ST1 and ST3 are connected to the first bit line BLe and the second and fourth memory strings ST2 and ST4 are connected to the second bit line BLo, the first through fourth memory strings ST1 to ST4 may be arranged to be zigzag.

Hereinafter, a method of operating a semiconductor memory device including the memory block having the above-described structure will be described. FIG. 7 is a waveform diagram illustrating a method of operating a semiconductor memory device according to an embodiment of the present invention.

Referring to FIGS. 4 and 7, a memory block may include memory strings ST1 to ST4 formed between BLe and BLo and a source line SL. The bit lines BLe and BLo and the source line SL may be formed on a substrate, and each (e.g., ST1) of the memory strings may include an superordinate cell string ST1d connected between the bit line (e.g., BLe) and a pipe transistor PT1 formed on the substrate, and a subordinate cell string ST1s connected between the source line SL and the pipe transistor PT1.

An operation circuit may apply operating voltages to the memory strings ST1 to ST4 to perform a program operation. In particular, the operation circuit may be configured to apply different voltages to gates PG1 and PG2 of pipe transistors PT1 and PT3 of the memory strings ST1 and ST3 connected to the same bit line (e.g., BLe) in the memory block. An example of the program operation will now be described in detail.

T1: First Period (Precharge Period)

The program operation may include a precharge period, a program period, and a discharge period. During the precharge period, a program inhibition voltage (i.e., Vinhibit) having a positive electric potential may be applied to an unselected bit line (e.g., BLe). A program inhibition voltage or program allowance voltage (e.g., ground voltage) may be applied to a selected bit line (e.g., BLo) according to data stored in a memory cell. For example, when data ‘1’ (or erase data) is stored in the memory cell, the program inhibition voltage may be applied to the selected bit line BLo. When data ‘0’ (or program data) is stored in the memory cell, a program allowance voltage may be applied to the selected bit line BLo.

A drain selection voltage Vdsl1 having a positive electric potential may be applied to a drain selection line DSL1 of a selected memory string (e.g., ST4) of the memory strings ST2 and ST4 connected to the selected bit line BLo. Also, a drain selection voltage (about 0V) having a ground level may be applied to a drain selection line DSL2 of an unselected memory string (e.g., ST2).

A ground voltage may be applied to a source selection line SSL, and a positive voltage (e.g., power supply voltage) may be applied to the source line SL. Meanwhile, a positive voltage (or pass voltage Vpass) may be applied to dummy pass word lines DPWL<0:3>.

In particular, the operation circuit may be configured to apply a voltage having a level B higher than a level A of a voltage (e.g., pass voltage) applied to a pipe gate PG1 of a pipe transistor PT4 included in the selected memory string ST4, to a pipe gate PG2 of a pipe transistor PT2 included in the unselected memory string ST2. The same voltage as a pass voltage applied to unselected word lines may be applied to the pipe gate PG1.

Since a voltage higher than the pass voltage is applied to the pipe transistor PT2 of the unselected memory string ST2, channel boosting may be improved in a channel region of the unselected memory string ST2. As a result, program disturbance of memory cells included in the unselected memory string ST2 may be improved during a subsequent program operation.

Meanwhile, at the program operation, to control a boosting level of the channel region of the unselected memory string ST2, the operation circuit may be configured to apply a voltage different from the pass voltage applied to the unselected word lines of the memory strings, to the dummy pass word lines DPWL0 to DPWL3. In an example, when the channel boosting level is increased, the operation circuit may boost the voltage applied to the dummy pass word lines DPWL0 to DPWL3. When the channel boosting level is reduced, the operation circuit may drop the voltage applied to the dummy pass word lines DPWL0 to DPWL3.

T2: Second Period (Program Period)

A program operation may be performed to store data in a memory cell.

To perform the program operation, the operation circuit may apply a pass voltage Vpass to word lines WL0 to WL15 and then apply a program voltage VPGM to a selected word line. In memory cells of the word line to which the program voltage VPGM is applied, electrons may be injected into a charge storage layer due to a high voltage difference between the word line and a channel.

In an unselected memory string, since channel boosting occurs and a voltage difference between the word line and the channel is low, electrons may not be injected into a charge storage layer of an unselected memory cell. In particular, since a pipe gate voltage having a higher level B is applied to the pipe gate PG2, channel boosting may occur more severely, and a voltage difference between the word line and the channel may be further reduced. Accordingly, the injection of electrons into the charge storage layer of the unselected memory cell may be further inhibited.

Meanwhile, the drain selection voltage Vdsl1 applied to the first drain selection line DSL1 may be reduced to a ground level to improve operating characteristics, and then a drain selection voltage Vdsl2 may be applied to the first drain selection line DSL1. In this case, initially, the drain selection voltage Vdsl1 may be applied at a level higher than a normal level.

T3: Third Period (Discharge Period)

When a program operation is ended, operation voltages applied to a memory block may be reduced to a ground level, and voltages applied to local lines may be discharged.

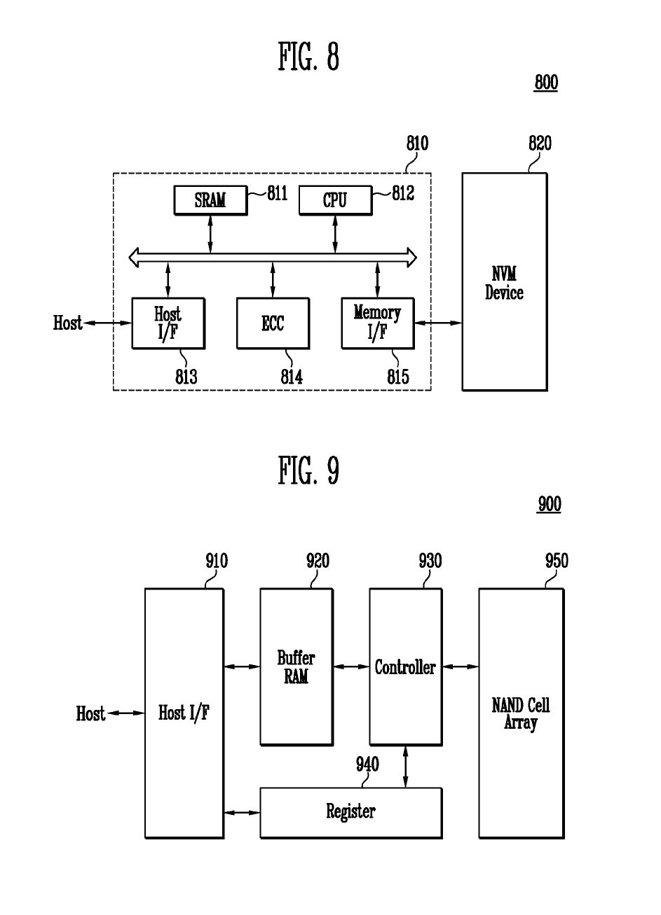

FIG. 8 is a block diagram of a memory system 800 according to an embodiment of the present invention.

Referring to FIG. 8, the memory system 800 according to embodiments of the present invention may include a nonvolatile memory (NVM) device 820 and a memory controller 810.

The nonvolatile memory device 820 may include the above-described semiconductor memory device. The memory system 800 may include the above-described semiconductor memory device to improve overall electrical properties.

The memory controller 810 may be configured to control the nonvolatile memory device 820. The nonvolatile memory device 820 and the memory controller 810 may be combined and provided as a memory card or a solid-state disk (SSD). A static random access memory (SRAM) 811 may be used as an operation memory of a processing unit 812 (i.e., CPU). A host interface (I/F) 813 may include a data exchange protocol of a host connected to the memory system 800. An error check and correct (ECC) block 814 may detect and correct errors in data read from a cell region of the nonvolatile memory device 820. A memory interface (I/F) 814 may interface with the nonvolatile memory device 820 according to the present invention. The processing unit 812 may perform general control operations for exchanging data of the memory controller 810.

Although not shown in the drawings, it would be apparent to those of ordinary skill in the art that the memory system 800 according to the present invention may further include a read-only memory (ROM) (not shown) configured to store code data for interfacing with the host. The nonvolatile memory device 820 may be provided as a multi-chip package including a plurality of flash memory chips. The above-described memory system 800 according to the present invention may be provided as a highly reliably storage medium having improved operating characteristics. In particular, a memory system (e.g., an SSD) into which brisk research has lately been conducted may include a flash memory device according to the present invention. In this case, the memory controller 810 may be configured to communicate with the outside (e.g., a host) through one of various interface protocols, such as a universal serial bus (USB), a multimedia card (MMC), peripheral component interface-express (PCI-E), serial advanced technology attachment (SATA), parallel-ATA (PATA), a small computer system interface (SCSI), an enhanced small device interface (ESDI), and an intelligent drive electronics (IDE).

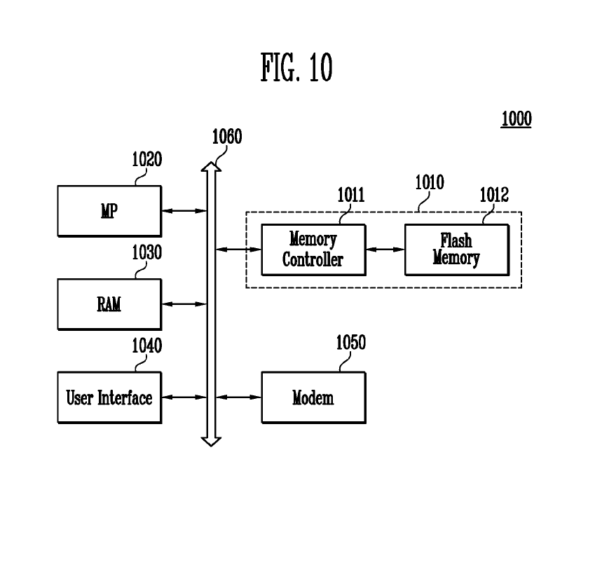

FIG. 9 is a block diagram of a fusion memory device or a fusion memory system configured to perform a program operation, according to an embodiment of the present invention. For example, technical features according to the present invention may be applied to a OneNAND flash memory device 900, which is a fusion memory device. By applying the above-described technical features according to the present invention to the fusion memory device or the fusion memory system, overall electrical properties may be improved.

The OneNAND flash memory device 900 may include a host interface 910 configured to exchange various pieces of information with devices using different protocols, a buffer RAM 920 configured to embed codes for driving the memory device 900 or temporarily store data, a controller 930 configured to control read and program operations and all states in response to external control signals and commands, a register 940 configured to store commands, addresses, and data (e.g., configuration data) configured to define system operating environments of the memory device 900, a NAND flash cell array 950 including nonvolatile memory cells and an operating circuit including a page buffer. The OneNAND flash memory device 900 may program data in a typical mode in response to a write request from the host.

FIG. 10 illustrates a schematic computing system 1000 including a flash memory device 1012 according to an embodiment of the present invention. The computing system may include the flash memory device 1012 having the above-described technical features to improve overall electrical properties of the computing system.

The computing system 1000 according to the present invention may include a memory controller 1011, a microprocessor (MP) 1020, a RAM 1030, a user interface 1040, a modem 1050 (e.g., a baseband chipset), and a memory system 1010, which may be electrically connected to a system bus 1060. When the computing system 1000 according to the present invention is a mobile device, the computing system 1000 may further include a battery (not shown) configured to supply an operating voltage to the computing system 1000. Although not shown in the drawings, it would be apparent to those of ordinary skill in the art that the computing system 1000 according to the present invention may further include an application chipset, a camera image processor (CIS), or a mobile dynamic RAM (mobile DRAM). The memory system 1010 may constitute an SSD using the nonvolatile memory described with reference to FIG. 1 to store data. Alternatively, the memory system 1010 may be provided as a fusion flash memory (e.g., OneNAND flash memory).

Various embodiments of the present invention can improve electrical properties of a semiconductor memory device.

In the drawings and specification, there have been disclosed typical examples of embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A semiconductor memory device comprising:
a first memory string including a first pipe transistor, a first superordinate cell string connected between a first bit line and the first pipe transistor, and a first subordinate cell string connected between the first pipe transistor and a source line;
a second memory string including a second pipe transistor, a second superordinate cell string connected between a second bit line and the second pipe transistor, and a second subordinate cell string connected between the second pipe transistor and the source line;
a third memory string including a third pipe transistor, a third superordinate cell string connected between the first bit line and the third pipe transistor, and a third subordinate cell string connected between the third pipe transistor and the source line; and
a fourth memory string including a fourth pipe transistor, a fourth superordinate cell string connected between the second bit line and the fourth pipe transistor, and a fourth subordinate cell string connected between the fourth pipe transistor and the source line,
wherein gates of the first and fourth pipe transistors are connected to each other, and gates of the second and third pipe transistors are connected to each other.

2. The device of claim 1, wherein each of the first through fourth subordinate cell strings includes a source selection transistor connected to the source line, and memory cells connected to the source selection transistor.

3. The device of claim 2, wherein each of the first through fourth subordinate cell strings further includes a first dummy pass memory cell connected between the source selection transistor and the memory cells.

4. The device of claim 2, wherein each of the first through fourth subordinate cell strings further includes a second dummy pass memory cell connected to a final memory cell of the memory cells.

5. The device of claim 1, wherein each of the first through fourth superordinate cell strings includes a drain selection transistor connected to the corresponding bit line and memory cells connected to the drain selection transistor,
wherein gates of drain selection transistors included in the first and fourth superordinate cell strings are connected to each other, and gates of drain selection transistors included in the second and third superordinate cell strings are connected to each other.

6. The device of claim 5, wherein each of the first through fourth superordinate cell strings further includes a third dummy memory cell connected to a final memory cell of the memory cells.

7. The device of claim 5, wherein each of the first through fourth superordinate cell strings further includes a fourth dummy transistor connected between the drain selection transistor and the memory cells.

8. A semiconductor memory device comprising:
first and second pipe gates formed on a substrate;
first and fourth horizontal channel layers formed in the first pipe gate;
second and third horizontal channel layers formed in the second pipe gate;
first conductive layers and second conductive layers stacked on different regions of the substrate;
a source line and bit lines formed on the first and second conductive layers;
second, third, sixth, and seventh vertical channel layers respectively connected between the first through fourth horizontal channel layers and the source line and formed through the first conductive layers;
first and fifth vertical channel layers respectively connected between the first and third horizontal channel layers and a first bit line through the second conductive layers; and
fourth and eighth vertical channel layers respectively connected between the second and fourth horizontal channel layers and a second bit line and formed through the second conductive layers.

9. The device of claim 8, further comprising charge storage layers interposed between the second, third, sixth, and seventh vertical channel layers and the first conductive layers and between the first, fourth, fifth, and eighth vertical channel layers and the second conductive layers.

10. The device of claim 8, wherein the first pipe gate is disposed to surround the second pipe gate.

11. The device of claim 8, wherein an uppermost conductive layer of the first conductive layers becomes a source selection line, and the remaining conductive layers become word lines.

12. The device of claim 11, wherein a conductive disposed under the uppermost conductive layer and a lowermost conductive layer become dummy pass word lines.

13. The device of claim 8, wherein an uppermost conductive layer of the second conductive layers becomes a drain selection line, and the remaining conductive layers become word lines.

14. The device of claim 13, wherein a conductive layer disposed under the uppermost conductive layer and a lowermost conductive layer become dummy pass word lines.

15. A semiconductor memory device comprising:
a memory block including memory strings formed between bit lines and a source line, wherein the bit lines and the source line are formed on a substrate, each of the memory strings includes a superordinate cell string connected between the bit line and pipe transistors formed on the substrate and a subordinate cell string connected between the source line and the pipe transistors; and
an operation circuit configured to apply operation voltages to the memory strings to perform a program operation and apply different voltages to the pipe transistors of the memory strings connected to the same bit line in the memory block.

16. The device of claim 15, wherein at the program operation, the operation circuit is configured to apply a voltage higher than a voltage applied to a pipe transistor of a selected memory string of the memory strings, to a pipe transistor of an unselected memory string.

17. The device of claim 16, wherein a pass voltage is applied to the pipe transistor of the selected memory string and unselected word lines.

18. The device of claim 17, wherein the pass voltage is applied to dummy pass word lines of the selected memory string.

19. The device of claim 15, wherein at the program operation, to control a boosting level in a channel region of an unselected memory string of the memory strings, the operation circuit is configured to apply a voltage different from a pass voltage applied to unselected word lines of the memory strings, to dummy pass word lines of the memory strings.

20. The device of claim 15, wherein gates of the pipe transistors of the memory strings connected to the same bit line in the memory block are separated from one another, and gates of the pipe transistors of memory strings connected to other bit lines are connected to one another.
